(19) United States
(12) Patent Application Publication
(10) Pub. No.: US 2023/0275150 A1
(43) Pub. Date: Aug. 31, 2023

(54) SEMICONDUCTOR DEVICE INCLUDING FERROELECTRIC MATERIAL AND ELECTRONIC DEVICE INCLUDING THE SEMICONDUCTOR DEVICE

(71) Applicant: Samsung Electronics Co., Ltd., Suwon-si (KR)

(72) Inventors: Hyunjae LEE, Suwon-si (KR); Jinseong HEO, Suwon-si (KR); Seunggeol NAM, Suwon-si (KR); Taehwan MOON, Suwon-si (KR); Hagyoul BAE, Suwon-si (KR)

(73) Assignee: Samsung Electronics Co., Ltd., Suwon-si (KR)

(21) Appl. No.: 18/168,699

(22) Filed: Feb. 14, 2023

(30) Foreign Application Priority Data
Feb. 28, 2022 (KR) 10-2022-0026304

(51) Int. Cl. H01L 29/78; H01L 29/76

(52) U.S. Cl. CPC H01L 29/78391; H01L 29/7606

(57) ABSTRACT

A semiconductor device may include a semiconductor substrate including a dopant having a polarity; a channel layer on the semiconductor substrate and including majority carriers having a polarity opposite to a polarity of the semiconductor substrate; a ferroelectric layer on the channel layer; and a gate on the ferroelectric layer. A doping concentration of the semiconductor substrate may be less than a concentration of the majority carrier of the channel layer.

### CROSS-REFERENCE TO RELATED APPLICATION

This application is based on and claims priority under 35 U.S.C. § 119 to Korean Patent Application No. 10-2022-0026304, filed on Feb. 28, 2022, in the Korean Intellectual Property Office, the disclosure of which is incorporated by reference herein in its entirety.

### BACKGROUND

### 1. Field

The disclosure relates to a semiconductor device including a ferroelectric material and an electronic device including the semiconductor device.

### 2. Description of the Related Art

A ferroelectric material is a material that has ferroelectricity and thus maintains a spontaneous polarization due to aligning of an internal electric dipole moment even when an electric field is not applied from the outside. The polarization (or electric field) remains semi-permanent within the ferroelectric material by applying a constant voltage and then bringing the voltage back to 0 V. Research has been made to apply such ferroelectric materials to logic devices or memory devices.

### SUMMARY

An example embodiment provides a semiconductor device using a ferroelectric material and an electronic device including the semiconductor device.

Additional aspects will be set forth in part in the description which follows and, in part, will be apparent from the description, or may be learned by practice of the presented embodiments of the disclosure.

According to an embodiment, a semiconductor device may include a semiconductor substrate including a dopant having a polarity; a channel layer on the semiconductor substrate and including majority carriers having a polarity opposite that of the semiconductor substrate; a ferroelectric layer on the channel layer; and a gate on the ferroelectric layer. The doping concentration of the semiconductor substrate may be lower than a concentration of the majority carriers of the channel layer.

In some embodiments, the doping concentration of the semiconductor substrate may be about 10¹⁶ to about 10¹⁹ cm⁻³. The concentration of the majority carriers of the channel layer may be about 10¹⁸ to about 10²¹ cm⁻³.

In some embodiments, the channel layer may have a thickness of 5 nm or less.

In some embodiments, the semiconductor substrate may include a group IV semiconductor material. The semiconductor substrate may include Si, Ge, or SiGe.

In some embodiments, the channel layer may include an oxide semiconductor or a two-dimensional (2D) semiconductor material.

In some embodiments, the dopant in the semiconductor substrate may be a p-type dopant.

In some embodiments, the channel layer may include an oxide of at least one of In, Ga, Zn, and Sn.

In some embodiments, the channel layer may include graphene or transition metal dichalcogenide (TMD). In some embodiments, the TMD may include a transition metal and a chalcogen element. The transition metal may include at least one of Mo, W, Nb, V, Ta, Ti, Zr, Hf, Co, Tc, and Re, and the chalcogen element may include at least one of S, Se, and Te.

In some embodiments, the dopant in the semiconductor substrate may be an n-type dopant.

In some embodiments, the channel layer may include an oxide of at least one of Sn and Ni.

In some embodiments, the channel layer may include black phosphorous.

In some embodiments, the ferroelectric layer may include at least one of hafnium oxide, zirconium oxide, and hafnium-zirconium oxide. The ferroelectric layer may be doped with at least one of Si, Al, La, Y, Sr, and Gd.

In some embodiments, the gate may comprise a metal or a metal nitride.

In some embodiments, the semiconductor device may include a source connected to a first side of the channel layer; and a drain connected to a second side of the channel layer. The first side and the second side may be different sides of the channel layer.

In some embodiments, the channel layer, the ferroelectric layer, and the gate may sequentially surround the semiconductor substrate.

According to an embodiment, a semiconductor device may include a substrate; and a first field effect transistor and a second field effect transistor on the substrate. The first field effect transistor may include a first semiconductor layer including a first dopant having a polarity; a first channel layer on the first semiconductor layer and including majority carriers having a polarity opposite that of the first semiconductor layer; a first ferroelectric layer on the first channel layer; and a first gate on the first ferroelectric layer. The second field effect transistor may include a second semiconductor layer including a second dopant having a polarity opposite that of the first semiconductor layer; a second channel layer on the second semiconductor layer and including majority carriers having a polarity opposite to that of the second semiconductor layer; a second ferroelectric layer on the second channel layer; and a second gate on the second ferroelectric layer. The doping concentration of the first semiconductor layer may be lower than the concentration of the majority carriers of the first channel layer, and the doping concentration of the second semiconductor layer may be lower than the concentration of the majority carriers of the second channel layer.

In some embodiments, the first channel layer and the second channel layer independently each may have a thickness of 5 nm or less.

In some embodiments, the first semiconductor layer and the second semiconductor layer independently each may include a group IV semiconductor material.

In some embodiments, the first second channel layer and the second channel layer independently each may include an oxide semiconductor or a two-dimensional semiconductor material.

In some embodiments, each of the first ferroelectric layer and the second ferroelectric layer may include at least one of hafnium oxide, zirconium oxide, and hafnium-zirconium oxide.

In some embodiments, the first channel layer may be directly on the first semiconductor layer, and an interface between the first channel layer and the first semiconductor layer may include a pn junction.

In some embodiments, the first field effect transistor may further include a first source connected to a first side of the first channel layer and a first drain connected to a second side of the first channel layer. The first side of the first channel layer and the second side of the first channel layer may be different sides of the first channel layer. The second field effect transistor may further include a second source connected to a first side of the second channel layer and a second drain connected to a second side of the second channel layer. The first side of the second channel layer and the second side of the second channel layer may be different sides of the second channel layer.

In some embodiments, the first ferroelectric layer may extend between the first source and the first drain, between the first gate and the first source, and between the first gate and the first drain. The second ferroelectric layer may extend between the second source and the second drain, between the second gate and the second source, and between the second gate and the second drain.

According to another embodiment, an electronic device may include one of the semiconductor devices described above.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view schematically illustrating a semiconductor device according to an example embodiment;

FIGS. 2A and 2B are views for explaining the operation of a conventional ferroelectric field effect transistor;

FIG. 3 illustrates a polarization state in a ferroelectric layer when a negative (−) voltage is applied to a gate of a semiconductor device according to an example embodiment;

FIG. 4 illustrates an example of an electron band bonding structure of a p-Si substrate and an IGZO channel layer in a semiconductor device according to an example embodiment;

FIGS. 5A and 5B are band diagrams illustrating a write operation of a semiconductor device according to an example embodiment;

FIG. 6 illustrates a semiconductor device according to another example embodiment;

FIG. 7 illustrates a semiconductor device according to another example embodiment;

FIG. 8 illustrates a semiconductor device according to another example embodiment;

FIG. 9 illustrates a semiconductor device according to another example embodiment;

FIG. 10 illustrates a semiconductor device according to another example embodiment;

FIG. 11 illustrates a semiconductor device according to another example embodiment;

FIG. 12 illustrates a semiconductor device according to another example embodiment;

FIG. 13 is a schematic circuit diagram of a memory device including a semiconductor device array;

FIG. 14 is a schematic block diagram of a display driver IC (DDI) and a display device having the DDI according to an example embodiment;

FIG. 15 is a block diagram of an electronic device according to an example embodiment;

FIG. 16 is a block diagram of an electronic device according to another example embodiment; and

FIGS. 17 and 18 are conceptual diagrams schematically illustrating a device architecture that can be applied to an electronic device according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, example embodiments will be described in detail with reference to the accompanying drawings. In the following drawings, the same reference numerals refer to the same components, and the size of each component in the drawings may be exaggerated for clarity and convenience of description. Meanwhile, the embodiments described below are merely examples and various modifications are possible from these embodiments.

Hereinafter, the term “upper portion” or “on” may also include “to be present on a non-contact basis” as well as “to be in directly contact with”. The singular expression includes plural expressions unless the context clearly implies otherwise. In addition, when a part “includes” a component, this means that it may further include other components, not excluding other components unless otherwise opposed.

The use of the term “the” and similar indicative terms may correspond to both singular and plural. If there is no explicit description of an order for steps that make up a method or vice versa, these steps can be done in an appropriate order and are not necessarily limited to the order described.

Further, the terms “unit”, “module” or the like mean a unit that processes at least one function or operation, which may be implemented in hardware or software or implemented in a combination of hardware and software.

The connection or connection members of lines between the components shown in the drawings represent functional connection and/or physical or circuit connections, and may be replaceable or represented as various additional functional connections, physical connections, or circuit connections in an actual device.

The use of all examples or example terms is simply to describe technical ideas in detail, and the scope is not limited by these examples or example terms unless the scope is limited by the claims.

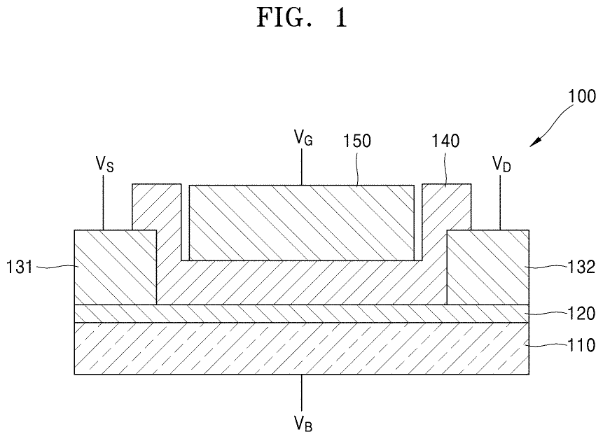

FIG. 1 is a cross-sectional view schematically illustrating a semiconductor device 100 according to an example embodiment. The semiconductor device 100 illustrated in FIG. 1 may be a ferroelectric field effect transistor (FeFET).

Referring to FIG. 1, the semiconductor device 100 includes a semiconductor substrate 110, a channel layer 120 provided on the semiconductor substrate 110, a ferroelectric layer 140 provided on the channel layer 120, and a gate 150 provided on the ferroelectric layer 140. A source 131 and A drain 132 are electrically connected to the channel layer 120 at both sides of the channel layer 120, respectively. In FIG. 1, “V_{S}” and “V_{D}” are the source voltage and the drain voltage applied to the source 131 and the drain 132, respectively, and “V_{G}” is the gate voltage applied to the gate 150. In addition, “V_{B}” is a body voltage applied to the semiconductor substrate 110 on which the channel layer 120 is formed.

The semiconductor substrate 110 may include a group IV semiconductor material doped with a dopant having a desired and/or alternatively predetermined polarity. Here, the group IV semiconductor material may include, for example, Si, Ge, or SiGe. However, embodiments are not limited thereto.

The dopant doped in the group IV semiconductor material may be a p-type dopant or an n-type dopant. The p-type dopant may include, for example, at least one of B, Al, Ga, and In. The n-type dopant may include, for example, at least one of P, As, and Sb. As an example, the semiconductor substrate 110 may be a p-Si substrate doped with a p-type dopant in Si or an n-Si substrate doped with an n-type dopant in Si. However, this is merely an example.

The doping concentration of the semiconductor substrate 110 may be less than that of majority carriers of the channel layer 120 to be described later. For example, the doping concentration of the dopant doped in the semiconductor substrate 110 may be approximately 10¹⁶ to 10¹⁹ cm⁻³. However, embodiments are not necessarily limited thereto.

The channel layer 120 is provided on the semiconductor substrate 110. The channel layer 120 may include an oxide semiconductor including majority carriers (electrons or holes) having a desired and/or alternatively predetermined polarity. The channel layer 120 may include an oxide semiconductor including majority carriers having a polarity opposite to that of the semiconductor substrate 110.

For example, when the semiconductor substrate 110 is doped with a p-type dopant, the channel layer 120 may include an n-type oxide semiconductor including electrons as the majority carriers. The n-type oxide semiconductor may comprise, for example, an oxide of at least one of In, Ga, Zn, and Sn. As an example, the n-type oxide semiconductor may include Indium Gallium Zinc Oxide (IGZO). However, this is merely an example.

For example, when the semiconductor substrate 110 is doped with an n-type dopant, the channel layer 120 may include a p-type oxide semiconductor including holes as the majority carriers. The p-type oxide semiconductor may comprise, for example, an oxide comprising at least one of Sn and Ni. As an example, the p-type oxide semiconductor may include SnO. However, this is merely an example.

The concentration of the majority carriers of the channel layer 120 may be greater than the doping concentration of the semiconductor substrate 110. For example, the concentration of the majority carriers of the channel layer 120 may be about 10¹⁸ to 10²¹ cm³. However, embodiments are not necessarily limited thereto. The channel layer 120 may be formed to have a relatively thin thickness so that tunneling of charges may be generated from the semiconductor substrate 110 to the channel layer 120. For example, the channel layer 120 may have a thin thickness of approximately 5 nm or less (e.g., 3 nm or less). However, embodiments are not limited thereto. The channel layer 120 may include an oxide semiconductor having a relatively low dielectric constant, for example, a dielectric constant of about 9 to 15. However, embodiments are not limited thereto.

The ferroelectric layer 140 is provided on the channel layer 120. A ferroelectric material is a material having ferroelectricity in which internal electric dipole moments are aligned to maintain a spontaneous polarization. The ferroelectric material has residual polarization due to the dipole even when an electric field is not applied from the outside. The polarization direction of the ferroelectric layer 140 may be changed by applying an electric field greater than or equal to a coercive field to the ferroelectric layer 140, and the threshold voltage of the semiconductor device 100 may be changed according to the polarization direction of the ferroelectric layer 140. In this regard, the semiconductor device 100 may be applied to, for example, a nonvolatile memory device.

The ferroelectric layer 140 may include, for example, a fluorite-based material, perovskite, or the like. The perovskite may include, for example, PZT, BaTiO₃, PbTiO₃, and the like. The fluoride-based material may include an oxide of at least one selected from, for example, Hf, Si, Al, Zr, Y, La, Gd, and Sr.

As an example, the ferroelectric layer 140 may include at least one of hafnium oxide (HfO), zirconium oxide (ZrO), and hafnium-zirconium oxide (HfZrO). The hafnium oxide (HfO), the zirconium oxide (ZrO), and the hafnium-zirconium oxide (HfZrO) constituting the ferroelectric layer 140 may have a crystal structure of an orthorhombic crystal system.

The ferroelectric layer 140 may further include a desired and/or alternatively predetermined dopant for controlling the remnant polarization and the coercive field of the ferroelectric layer 140. For example, the dopant may include at least one selected from Si, Al, Y, La, Gd, Mg, Ca, Sr, Ba, Ti, Zr, Hf and N. However, this is merely an example. The remnant polarization of the ferroelectric layer 140 may be determined by the type of the ferroelectric material, the type of the dopant, the ratio of the dopant, the orientation, and the like.

The gate 150 is provided on the ferroelectric layer 140. The gate 150 may have a conductivity of, for example, about 1 Mohm/square or less. However, embodiments are not limited thereto. The gate 150 may include a metal or a metal nitride. For example, the metal may include aluminum (Al), tungsten (W), molybdenum (Mo), titanium (Ti), or tantalum (Ta), and the metal nitride may include titanium nitride (TiN) or tantalum nitride (TaN).

The gate 150 may include metal carbide, polysilicon, or a two-dimensional conductive material. The metal carbide may be aluminum or silicon-doped (or contained) metal carbide. As an example, the metal carbide may include TiAlC, TaAlC, TiSiC, or TaSiC. The gate 150 may have a structure in which a plurality of materials are stacked. For example, the gate 150 may have a stacked structure of a metal nitride layer/metal layer such as TiN/Al or a laminated structure of a metal nitride layer/metal carbide layer/metal layer such as TiN/TiAlC/W.

As described above, in the semiconductor device 100 according to the present embodiment, a channel having a p-n junction may be formed between the semiconductor substrate 110 and the channel layer 120 by adjusting the doping concentration of the semiconductor substrate 110 to be lower than that of the majority carriers of the channel layer 120 and the thickness of the channel layer 120 to be thin. The semiconductor substrate 110 may change the polarization direction of the ferroelectric layer with a relatively low voltage by supplying, to the channel layer 120, minority carriers (holes or electrons) capable of helping a depletion operation and an inversion operation of the channel layer 120. Accordingly, a large memory window (MW) and an excellent retention characteristic of the semiconductor device 100 may be secured.

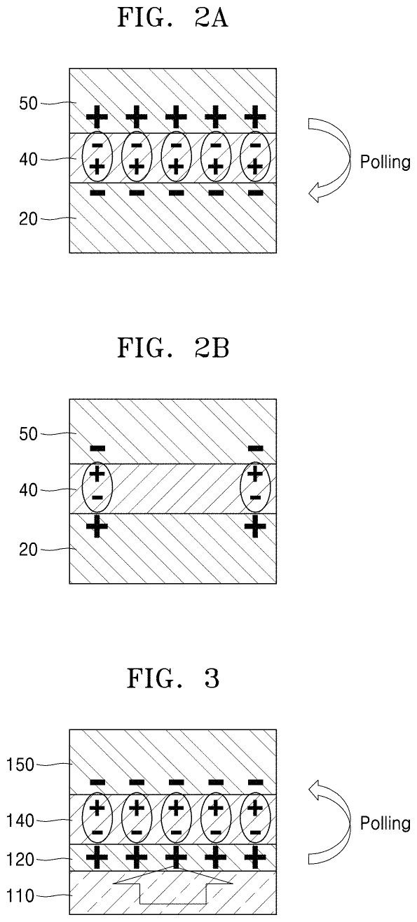

FIGS. 2A and 2B are views for explaining the operation of a conventional ferroelectric field effect transistor 10.

Referring to FIGS. 2A and 2B, the conventional ferroelectric field effect transistor 10 includes a channel layer 20 including an oxide semiconductor having majority carriers having a desired and/or alternatively predetermined polarity, a ferroelectric layer 40 provided on the channel layer 20, and a gate 50 provided on the ferroelectric layer 40. In FIGS. 2A and 2B, a case where the channel layer 20 includes an n-type oxide semiconductor (e.g., IGZO) having electrons as majority carriers is illustrated as an example.

FIG. 2A illustrates a polarization state in the ferroelectric layer 40 when a positive (+) voltage is applied to the gate 50, and FIG. 2B illustrates a polarization state in the ferroelectric layer 40 when a negative (−) voltage is applied to the gate 50.

In order to change the polarization direction of the ferroelectric layer 40, an electric field equal to or greater than a coercive field should be applied to the ferroelectric layer 40. However, in the conventional ferroelectric field effect transistor 10, since holes, which are minority carriers, are insufficient in the channel layer 20, charge screening does not occur when a negative (−) voltage is applied to the gate 50 as illustrated in FIG. 2B, and thus the polarization direction of the ferroelectric layer 40 cannot be changed. Accordingly, in the conventional ferroelectric field effect transistor 10, the memory window MW may be small, and the retention characteristic may be deteriorated.

FIG. 3 illustrates a polarization state in the ferroelectric layer 140 when a negative (−) voltage is applied to the gate 150 in the semiconductor device 100 according to an example embodiment. In FIG. 3, a case in which a semiconductor substrate is formed of a group IV semiconductor material (for example, p-Si) doped with a p-type dopant and a channel layer is formed of an n-type oxide semiconductor (for example, IGZO) is illustrated as an example. Here, the doping concentration of the semiconductor substrate 110 is lower than that of majority carriers of the channel layer 120, and the channel layer 120 has a thickness of 5 nm or less.

Referring to FIG. 3, when a negative (−) voltage is applied to the gate 150, the semiconductor substrate 110 doped with the p-type dopant may change the polarization direction of the ferroelectric layer 140 by supplying holes, which are minority carriers of the channel layer 120, by a tunneling effect, on the channel layer 120 including the n-type oxide semiconductor. Therefore, since the polarization direction of the ferroelectric layer 140 may be changed even at a relatively low voltage, the semiconductor device 100 having a large memory window MW and an excellent retention characteristic may be implemented.

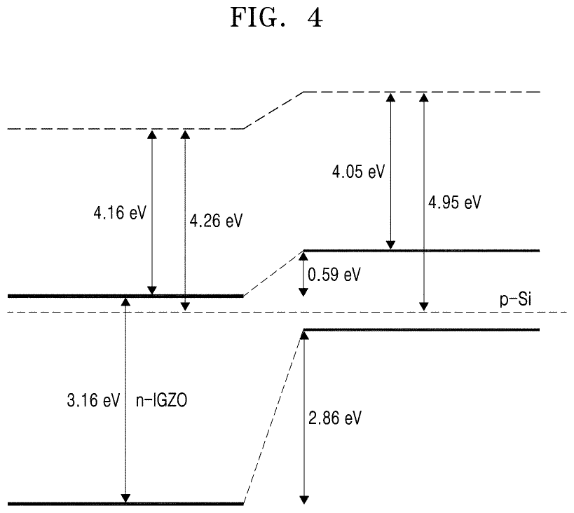

FIG. 4 illustrates an example of an electron band bonding structure of a p-Si substrate and an IGZO channel layer in a semiconductor device 100 according to an example embodiment. In FIG. 4, a p-Si substrate in which boron (B), which is a p-type dopant, is doped in Si, was used as the semiconductor substrate 110, and an IGZO channel layer, which is an n-type oxide semiconductor, was used as the channel layer 120. Here, the concentration of majority carriers (e.g., electrons) of the IGZO channel layer 120 was approximately 10²¹ cm⁻³.

The Fermi level of the p-Si substrate shown in FIG. 4 represents a value when the doping concentration of the p-Si substrate is 10¹⁶ cm⁻³. The IGZO channel layer and the p-Si substrate have electron affinity of 4.16 eV and 4.05 eV, respectively, and the work functions of the IGZO channel layer and the p-Si substrate are 4.26 eV and 4.95 eV, respectively. As shown in FIG. 4, it may be seen that the p-Si substrate and the IGZO channel layer form a p-n junction.

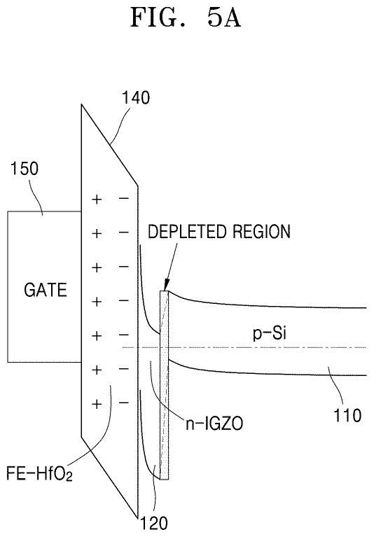

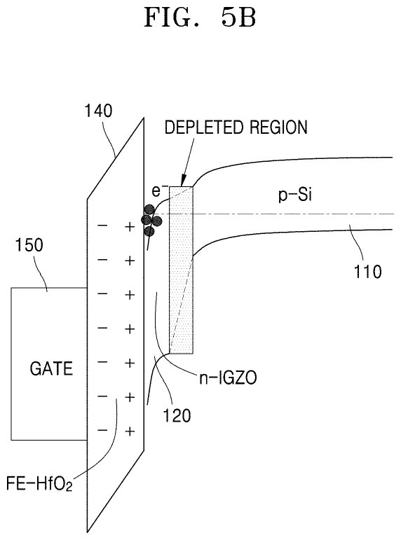

FIGS. 5A and 5B are band diagrams illustrating a write operation of a semiconductor device 100 according to an example embodiment. In the drawings, a case in which the p-Si substrate was used as the semiconductor substrate 110, the IGZO channel layer was used as the channel layer 120, and the HfO₂ ferroelectric layer was used as the ferroelectric layer 140 is illustrated as an example.

In FIG. 5A, an erase process for writing “0” in the semiconductor device 100 according to an example embodiment is illustrated. In the erase process, a negative (−) coercive voltage (−V_{c}) is applied to the gate, and a positive (+) body voltage (+V_{b}) is applied to the IGZO channel layer.

Referring to FIG. 5A, when a negative (−) coercive voltage is applied to the gate, the IGZO channel layer is depleted and tunneling (Fowler-Nordheim (F-N) tunneling) according to application of a strong electric field may be induced. Accordingly, hole carriers in the p-Si substrate may traverse the depleted region of the IGZO channel layer to form compression charges for polarization change (polling) of the HfO₂ ferroelectric layer. Accordingly, the polarization of the HfO₂ ferroelectric layer may be changed to “0”.

In FIG. 5B, a program process for writing “1” in the semiconductor device 100 according to an example embodiment is illustrated. In the program process, the positive (+) coercive voltage +V_{c} is applied to the gate and the body voltage applied to the channel layer is floated.

Referring to FIG. 5B, electrons are accumulated in the IGZO channel layer when a positive (+) coercive voltage is applied to the gate. In this case, due to the application of the reverse bias, a depleted region between the IGZO channel layer and the p-Si substrate increases, and thus tunneling of the hole carriers is limited. Accordingly, the polarization of the HfO₂ ferroelectric layer may be changed to “1”.

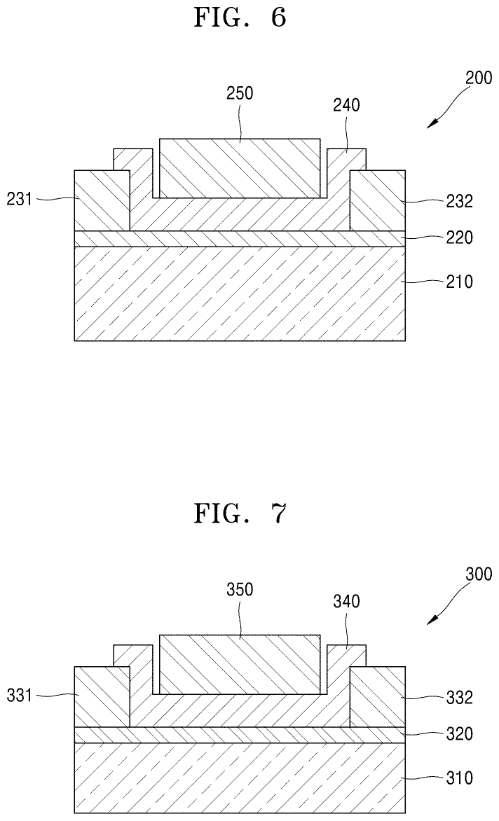

FIG. 6 illustrates a semiconductor device 200 according to another example embodiment. Hereinafter, differences from the above-described embodiment will be mainly described.

Referring to FIG. 6, the semiconductor device 200 includes a semiconductor substrate 210, a channel layer 220 provided on the semiconductor substrate 210, a ferroelectric layer 240 provided on the channel layer 220, and a gate 250 provided on the ferroelectric layer 240. A source 231 and a drain 232 are provided on both sides of the channel layer 220, respectively.

The semiconductor substrate 210 may include a group IV semiconductor material doped with a p-type dopant. The group IV semiconductor material may include, for example, Si, Ge, or SiGe. The p-type dopant may include, for example, at least one of B, Al, Ga, and In. For a specific example, the semiconductor substrate 210 may be a p-Si substrate in which a p-type dopant is doped in Si, but is not limited thereto.

The doping concentration of the semiconductor substrate 210 may be less than that of majority carriers of the channel layer 220 to be described later. For example, the doping concentration of the dopant doped in the semiconductor substrate 210 may be approximately 10¹⁶ to 10¹⁹ cm⁻³. However, embodiments are not limited thereto.

The channel layer 220 is provided on the semiconductor substrate 210. The channel layer 220 may include a two-dimensional semiconductor material having, as majority carriers, charges (e.g., electrons) having a polarity opposite to that of the semiconductor substrate 210. The two-dimensional semiconductor material has a structure in which the constituent atoms are two-dimensionally bonded, and means a material having semiconductor characteristics. The two-dimensional semiconductor material may include a monolayer or a multilayer, and each layer constituting the two-dimensional semiconductor material may have an atomic level thickness.

The n-type two-dimensional semiconductor material having electrons as majority carriers may include, for example, graphene or transition metal dichalcogenide (TMD). Graphene refers to a material having a hexagonal honeycomb structure in which carbon atoms are two-dimensionally bonded. The TMD is a compound of a transition metal and a chalcogen element. Here, the transition metal may include at least one of, for example, Mo, W, Nb, V, Ta, Ti, Zr, Hf, Co, Tc, and Re, and the chalcogen element may include at least one of, for example, S, Se, and Te. As an example, the TMD may include MoS₂, MoSe₂, MoTe₂, WS₂, WSe₂, WTe₂, ZrS₂, ZrSe₂, HfS₂, HfSe₂, NbSe₂, ReSe₂, and the like. However, embodiments are not limited thereto.

The concentration of the majority carriers of the channel layer 220 may be greater than the doping concentration of the semiconductor substrate 210. For example, the concentration of the majority carriers of the channel layer 220 may be about 10¹⁸ to 10²¹ cm⁻³. However, this is merely an example. For example, the channel layer 220 may have a thin thickness of approximately 5 nm or less (e.g., 3 nm or less).

The ferroelectric layer 240 is provided on the channel layer 220. The ferroelectric layer 240 may include, for example, a fluorite-based material, perovskite, or the like. The perovskite may include, for example, PZT, BaTiO₃, PbTiO₃, and the like. The fluoride-based material may include an oxide of at least one selected from, for example, Hf, Si, Al, Zr, Y, La, Gd, and Sr. As an example, the ferroelectric layer 240 may include at least one of hafnium oxide (HfO), zirconium oxide (ZrO), and hafnium-zirconium oxide (HfZrO).

The ferroelectric layer 240 may further include a desired and/or alternatively predetermined dopant. Here, the dopant may include at least one selected from Si, Al, Y, La, Gd, Mg, Ca, Sr, Ba, Ti, Zr, Hf and N. However, this is merely an example. The gate 250 is provided on the ferroelectric layer 240. The gate 250 may include a metal, a metal nitride, a metal carbide, polysilicon, or a two-dimensional conductive material.

The semiconductor device 200 according to the present embodiment may change the polarization direction of the ferroelectric layer 240 by supplying holes that are minority carriers to the channel layer 220 in which the semiconductor substrate 210 doped with the p-type dopant has electrons as majority carriers. In addition, since the channel layer 220 including the two-dimensional semiconductor material may control the thickness by atomic layer level, the inversion layer can be induced at a lower voltage at a forward bias. In addition, the semiconductor device 200 having improved durability may be implemented by forming the channel layer 220 as a two-dimensional semiconductor material.

FIG. 7 illustrates a semiconductor device 300 according to another example embodiment. Hereinafter, differences from the above-described embodiment will be mainly described.

Referring to FIG. 7, the semiconductor device 300 includes a semiconductor substrate 310, a channel layer 320 provided on the semiconductor substrate 310, a ferroelectric layer 340 provided on the channel layer 320, and a gate 350 provided on the ferroelectric layer 340. A source 331 and a drain 332 are provided on both sides of the channel layer 320, respectively.

The semiconductor substrate 310 may include a group IV semiconductor material doped with an n-type dopant. The group IV semiconductor material may include, for example, Si, Ge, or SiGe. The n-type dopant may include, for example, at least one of P, As, and Sb. For a specific example, the semiconductor substrate 310 may be an n-Si substrate in which an n-type dopant is doped in Si, but this is merely an example.

The doping concentration of the semiconductor substrate 310 may be less than that of majority carriers of the channel layer 320 to be described later. For example, the doping concentration of the dopant doped in the semiconductor substrate 310 may be approximately 10¹⁶ to 10¹⁹ cm⁻³. However, embodiments are not limited thereto.

The channel layer 320 is provided on the semiconductor substrate 310. The channel layer 320 may include a two-dimensional semiconductor material having, as majority carriers, charges (e.g., holes) having a polarity opposite to that of the semiconductor substrate 310. The p-type two-dimensional semiconductor material having holes as majority carriers may comprise, for example, a black phosphorous (BP). The black phosphorus (BP) is a semiconductor material having a structure in which phosphorus (P) atoms are two-dimensionally bonded.

The concentration of the majority carriers of the channel layer 320 may be greater than the doping concentration of the semiconductor substrate 310. For example, the concentration of the majority carriers of the channel layer 320 may be about 10¹⁸ to 10²¹ cm⁻³. However, this is merely an example. The channel layer 320 may have a thin thickness of approximately 5 nm or less (e.g., 3 nm or less).

The ferroelectric layer 340 is provided on the channel layer 320. As an example, the ferroelectric layer 240 may include at least one of hafnium oxide (HfO), zirconium oxide (ZrO), and hafnium-zirconium oxide (HfZrO). The ferroelectric layer 340 may further include a desired and/or alternatively predetermined dopant. The gate 350 is provided on the ferroelectric layer 340.

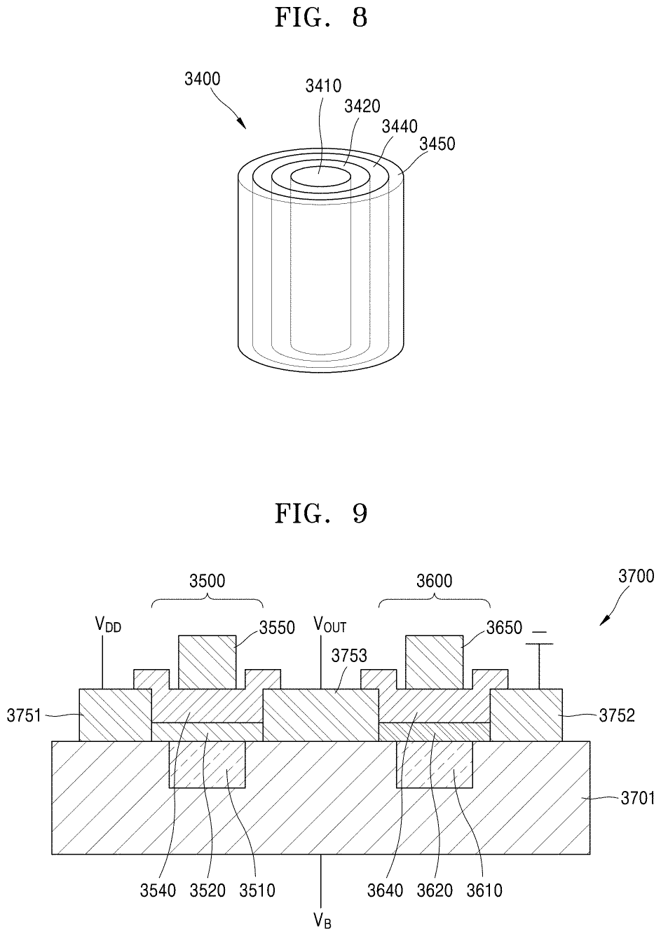

FIG. 8 illustrates a semiconductor device 3400 according to another example embodiment. The semiconductor device 3400 illustrated in FIG. 8 may be a ferroelectric field effect transistor having a gate-all-around (GAA) structure.

Referring to FIG. 8, the semiconductor device 3400 includes a semiconductor substrate 3410, a channel layer 3420, a ferroelectric layer 3440, and a gate 3450. Here, the channel layer 3420, the ferroelectric layer 3440 and the gate 3450 are provided to sequentially surround the semiconductor substrate 3410.

The semiconductor substrate 3410 may include a group IV semiconductor material doped with a dopant having a desired and/or alternatively predetermined polarity. Here, the group IV semiconductor material may include, for example, Si, Ge, or SiGe. The dopant doped in the group IV semiconductor material may be a p-type dopant or an n-type dopant. For example, the semiconductor substrate 3410 may be a p-Si substrate or an n-Si substrate, but this is merely an example. The doping concentration of the semiconductor substrate 3410 may be less than that of majority carriers of the channel layer 3420 to be described later. For example, the doping concentration of the dopant doped in the semiconductor substrate 3410 may be approximately 10¹⁶ to 10¹⁹ cm⁻³.

The channel layer 3420 is provided to surround the semiconductor substrate 3410. The channel layer 3420 may include majority carriers having a polarity opposite to that of the semiconductor substrate 3410. The channel layer 3420 may include an oxide semiconductor or a two-dimensional semiconductor material.

When the semiconductor substrate 3410 is doped with a p-type dopant, the channel layer 3420 may include an n-type oxide semiconductor or an n-type two-dimensional semiconductor material, which includes electrons as the majority carriers. The n-type oxide semiconductor may comprise, for example, an oxide of at least one of In, Ga, Zn, and Sn. The n-type two-dimensional semiconductor material may include, for example, graphene or TMD.

When the semiconductor substrate 3410 is doped with an n-type dopant, the channel layer 3420 may include a p-type oxide semiconductor or a p-type two-dimensional semiconductor material, which includes holes as the majority carriers. The p-type oxide semiconductor may comprise, for example, an oxide comprising at least one of Sn and Ni. The p-type two-dimensional semiconductor material may include, for example, a black phosphorous (BP). However, this is merely an example.

The concentration of the majority carriers of the channel layer 3420 may be greater than the doping concentration of the semiconductor substrate 3410. For example, the concentration of the majority carriers of the channel layer 3420 may be about 10¹⁸ to 10²¹ cm³. However, embodiments are not necessarily limited thereto. The channel layer 3420 may have a thin thickness of approximately 5 nm or less (e.g., 3 nm or less), but is not limited thereto.

The ferroelectric layer 3440 is provided to surround the channel layer 3420. The ferroelectric layer 3440 may include at least one of, for example, hafnium oxide (HfO), zirconium oxide (ZrO), and hafnium-zirconium oxide (HfZrO). The ferroelectric layer 3440 may further include a desired and/or alternatively predetermined dopant. The gate 3450 is provided to surround the ferroelectric layer 3440.

FIG. 9 illustrates a semiconductor device 3700 according to another example embodiment. The semiconductor device 3700 illustrated in FIG. 9 may be, for example, an inverter used to construct a logic circuit such as a NOR flash or a NAND flash.

Referring to FIG. 9, the semiconductor device 3700 includes first and second field effect transistors 3500 and 3600 provided on the substrate 3701. Here, each of the first and second field effect transistors 3500 and 3600 may be the ferroelectric field effect transistors described above. A Si substrate may be used as the substrate 3701, but this is only an example.

The first field effect transistor 3500 includes a first semiconductor layer 3510, a first channel layer 3520 provided on the first semiconductor layer 3510, a first ferroelectric layer 3540 provided on the first channel layer 3520, and a first gate 3550 provided on the first ferroelectric layer 3540. A first source 3751 and a drain 3753 are provided on both sides of the first channel layer 3520, respectively.

The first semiconductor layer 3510 may include a group IV semiconductor material doped with a desired and/or alternatively predetermined dopant, for example, an n-type dopant. As an example, the first semiconductor layer 3510 may include n-Si, but is not limited thereto. The first channel layer 3520 may include an oxide semiconductor or a two-dimensional semiconductor material including majority carriers having a polarity opposite to that of the first semiconductor layer 3510. For example, when the first semiconductor layer 3510 is doped with an n-type dopant, the first channel layer 3520 may include a p-type oxide semiconductor or a p-type two-dimensional semiconductor material having holes as majority carriers. The p-type oxide semiconductor may comprise, for example, an oxide comprising at least one of Sn and Ni. The p-type two-dimensional semiconductor material may include, for example, a black phosphorous (BP). However, this is merely an example.

The doping concentration of the first semiconductor layer 3510 may be less than that of majority carriers of the first channel layer 3520. For example, the doping concentration of the first semiconductor substrate 3510 may be approximately 10¹⁶ to 10¹⁹ cm⁻³, and the concentration of the majority carriers of the first channel layer 3520 may be about 10¹⁸ to 10²¹ cm⁻³. The first channel layer 3520 may have a thin thickness of approximately 5 nm or less, but is not limited thereto. The first ferroelectric layer 3540 is provided on the first channel layer 3520, and the first gate 3550 is provided on the first ferroelectric layer 3540.

The second field effect transistor 3600 includes a second semiconductor layer 3610, a second channel layer 3620 provided on the second semiconductor layer 3610, a second ferroelectric layer 3640 provided on the second channel layer 3620, and a second gate 3650 provided on the second ferroelectric layer 3640. The drain 3753 and a second source 3752 are provided on both sides of the second channel layer 3620, respectively. The drain 3753 may be a common drain of the first and second field effect transistors 3500 and 3600.

The second semiconductor layer 3610 may include a group IV semiconductor material doped with a dopant having a polarity opposite to that of the first semiconductor layer 3510. For example, when the first semiconductor layer 3510 is doped with an n-type dopant, the second semiconductor layer 3610 may include a group IV semiconductor material doped with a p-type dopant. For example, the second semiconductor layer 3610 may include p-Si, but this is only an example.

The second channel layer 3620 may include an oxide semiconductor or a two-dimensional semiconductor material including majority carriers having a polarity opposite to that of the second semiconductor layer 3610. For example, when the second semiconductor layer 3610 is doped with a p-type dopant, the second channel layer 3620 may include an n-type oxide semiconductor or an n-type two-dimensional semiconductor material having electrons as majority carriers. The n-type oxide semiconductor may comprise, for example, an oxide of at least one of In, Ga, Zn, and Sn. The n-type two-dimensional semiconductor material may include, for example, graphene or TMD.

The doping concentration of the second semiconductor layer 3610 may be less than that of majority carriers of the second channel layer 3620. For example, the doping concentration of the second semiconductor layer 3610 may be approximately 10¹⁶ to 10¹⁹ cm⁻³, and the concentration of the majority carriers of the second channel layer 3620 may be about 10¹⁸ to 10²¹ cm⁻³. The second channel layer 3620 may have a thin thickness of approximately 5 nm or less, but is not limited thereto. The second ferroelectric layer 3640 is provided on the second channel layer 3620, and the second gate 3650 is provided on the second ferroelectric layer 3640.

The above-described semiconductor devices (ferroelectric field effect transistors) may be employed in various electronic devices. For example, the semiconductor devices described above may be used as logic transistors or memory transistors. In addition, the above-described semiconductor devices may be used as memory cells. A plurality of memory cells are arranged two-dimensionally, in one direction vertical or horizontal, or in one direction to form memory string cells. A memory cell array may be achieved by arranging a plurality of memory string cells in a two-dimensional arrangement.

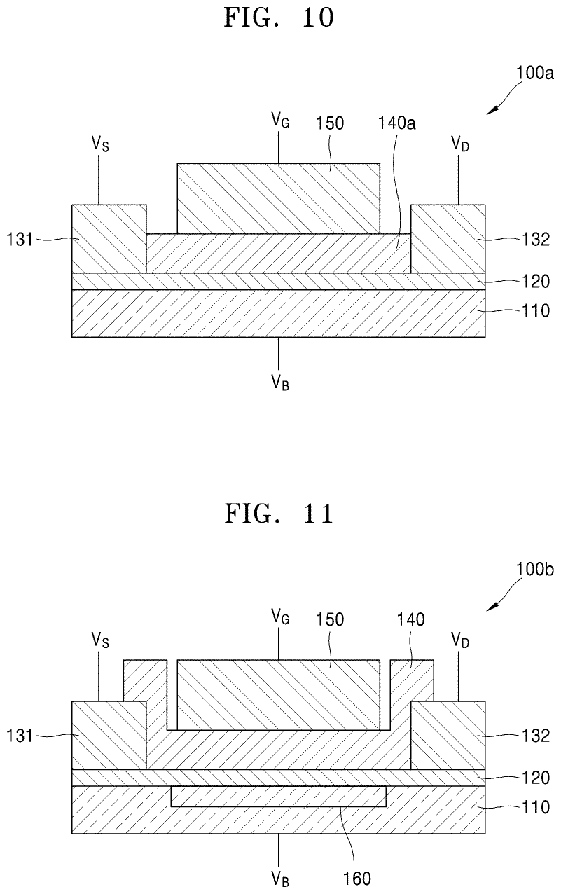

FIG. 10 illustrates a semiconductor device according to another example embodiment.

Referring to FIG. 10, the semiconductor device 100a may be the same as the semiconductor device 100 in FIG. 1, except for a structure of the ferroelectric layer 140a. The ferroelectric layer 140a may contact sidewalls of the source 131 and drain 132, but does not extend onto upper surfaces of the source 131 and drain 132.

FIG. 11 illustrates a semiconductor device according to another example embodiment.

Referring to FIG. 11, the semiconductor device 100b may be the same as the semiconductor device 100 in FIG. 1, except the semiconductor substrate 110 of the semiconductor device 100b may have a region 160 with a different dopant concentration than an area of the semiconductor substrate 110 surrounding the region 160. For example the region 160 may have greater concentration of the dopant having a desired and/or alternatively predetermined polarity than the area of the area of the semiconductor substrate 110 surrounding the region 160. The region 160 may be under the gate 150 and may not be under the source 131 and drain 132.

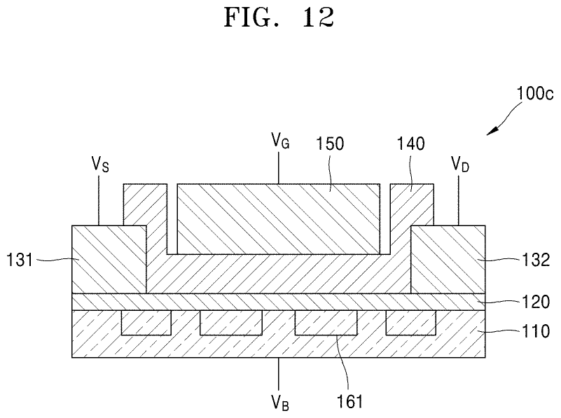

FIG. 12 illustrates a semiconductor device according to another example embodiment.

Referring to FIG. 12, the semiconductor device 100c may be similar to semiconductor device 100b in FIG. 11, except the semiconductor substrate 110 of the semiconductor device 100c may have a plurality of regions 161 with a different dopant concentrations than an area of the semiconductor substrate 110 surrounding the regions 161. For example the regions 161 may have a greater concentration of the dopant having a desired and/or alternatively predetermined polarity than the areas of the semiconductor substrate 110 surrounding the regions 161.

In addition, the above-described semiconductor devices may form part of an electronic circuit constituting an electronic device together with other circuit elements such as a capacitor.

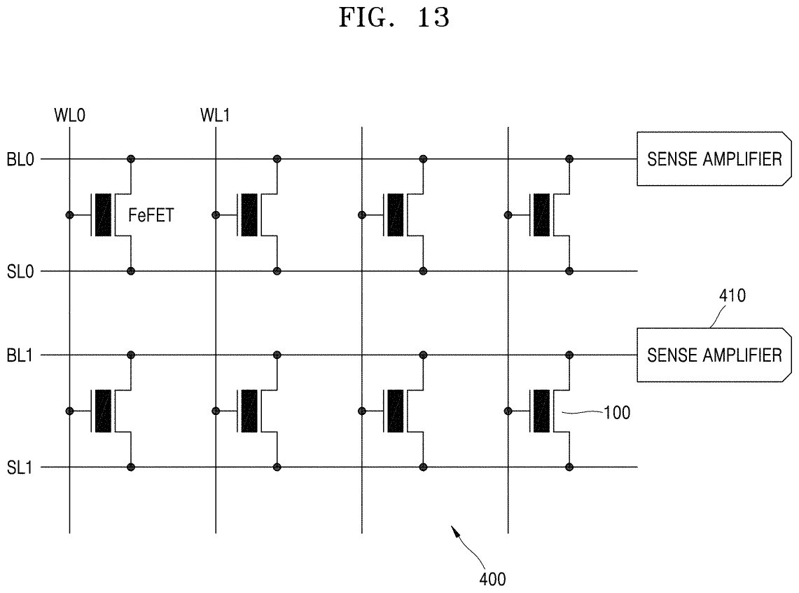

FIG. 13 is a schematic circuit diagram of a memory device including a semiconductor device array.

Referring to FIG. 13, the memory device 400 may include an array of a plurality of semiconductor devices 100 arranged in two dimensions. In addition, the memory device 400 may include a plurality of bit lines BL0 and BL1, a plurality of selection lines SL0 and SL1, and a plurality of word lines WL0 and WL1. Each of the selection lines SL0 and SL1 may be electrically connected to the first source/drain region of the semiconductor device 100, each of the bit lines BL0 and BL1 may be electrically connected to the second source/drain region of the semiconductor device 100, and each of the plurality of word lines WL0 and WL1 may be electrically connected to the gate electrode of the semiconductor device 100. In addition, the memory device 400 may further include an amplifier 410 for amplifying a signal output from each of the bit lines BL0 and BL1. While FIG. 13 includes the semiconductor device 100, example embodiments are not limited thereto. Each of the semiconductor devices 100, 100a, 100b, 100c, 200, and 300 may be one memory cell of the memory device 400.

Although FIG. 13 is illustrated as a two-dimensional plane for convenience, the memory device 400 may have a stacked structure of two or more stages. For example, the plurality of bit lines BL0 and BL1 and the plurality of selection lines SL0 and SL1 extending in a vertical direction may be two-dimensionally arranged, and the plurality of word lines WL0 and WL1 extending in a horizontal direction may be arranged on a plurality of layers, respectively. However, embodiments are not necessarily limited thereto, and memory cells may be arranged in three dimensions in various ways.

The above-described semiconductor devices (ferroelectric field effect transistors) may also be applied to an artificial intelligence device (not shown). Each memory cell constituting the artificial intelligence device includes one transistor and one ferroelectric field effect transistor. As a synaptic weight is applied to a transistor, the potential is transferred to the ferroelectrics, thereby changing the memory state. Here, when a potential greater than a threshold voltage is applied to the ferroelectrics, a neuron-synaptic action in which the potential of the pre-synaptic neuron is transferred to the post-synaptic neuron may occur.

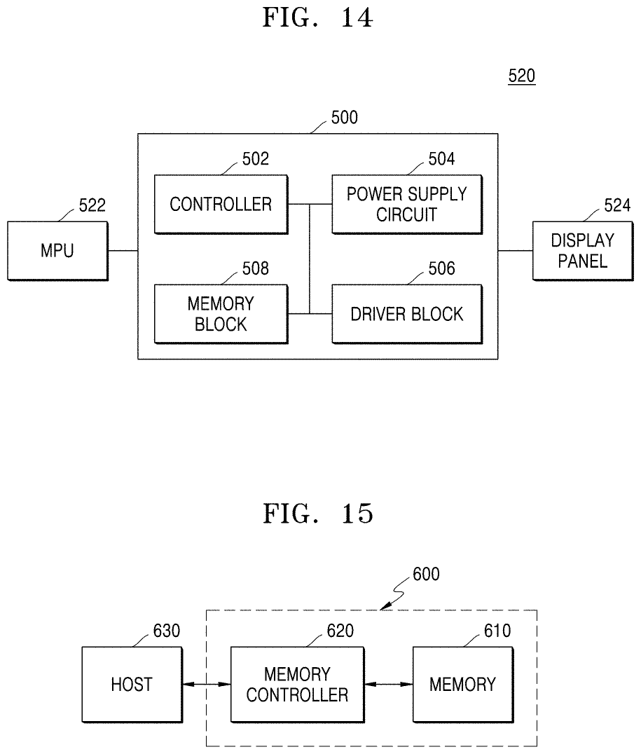

FIG. 14 is a schematic block diagram of a display driver IC (DDI) 500 and a display device 520 having the DDI 500 according to an example embodiment.

Referring to FIG. 14, the DDI 500 may include a controller 502, a power supply circuit 504, a driver block 506, and a memory block 508. The controller 502 receives and decodes a command applied from a main processing unit (MPU) 522, and controls each block of the DDI 500 to implement an operation according to the command. The power supply circuit 504 generates a driving voltage in response to the control of the controller 502. The driver block 506 drives a display panel 524 using the driving voltage generated by the power supply circuit 504 in response to the control of the controller 502. The display panel 524 may be, for example, a liquid crystal display panel, an organic light emitting device (OLED) display panel, or a plasma display panel. The memory block 508 is a block that temporarily stores a command input to the controller 502 or control signals output from the controller 502 or stores necessary data, and may include a memory such as RAM, ROM, or the like. For example, the memory block 508 may include semiconductor devices according to the above-described embodiments.

FIG. 15 is a block diagram of an electronic device 600 according to an example embodiment.

Referring to FIG. 15, the electronic device 600 includes a memory 610 and a memory controller 620. The memory controller 620 may control the memory 610 to read data from the memory 610 and/or write data to the memory 610 in response to a request from a host 630. The memory 610 may include a semiconductor device according to the embodiments described above.

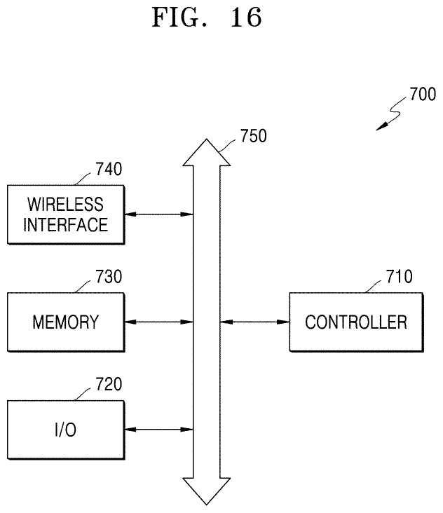

FIG. 16 is a block diagram of an electronic device 700 according to an example embodiment.

Referring to FIG. 16, the electronic device 700 may configure a wireless communication device or a device capable of transmitting and/or receiving information under a wireless environment. The electronic device 700 includes a controller 710, an input/output device (I/O) 720, a memory 730, and a wireless interface 740, each of which is interconnected through a bus 750.

The controller 710 may include at least one of a microprocessor, a digital signal processor, or a processing device similar thereto. The input/output device 720 may include at least one of a keypad, a keyboard, or a display. The memory 730 may be used to store a command executed by the controller 710. For example, the memory 730 may be used to store user data. The electronic device 700 may use the wireless interface 740 to transmit/receive data through a wireless communication network. The wireless interface 740 may include an antenna and/or a wireless transceiver. In some embodiments, the electronic device 700 may be used in a communication interface protocol of a third generation communication system, such as Code Division Multiple Access (CDMA), Global System for Mobile Communications (GSM), North American Digital Cellular (NADC), Extended-Time Division Multiple Access (E-TDMA), and/or Wideband Code Division Multiple Access (WCDMA). The memory 730 of the electronic device 700 may include a semiconductor device according to the embodiments described above.

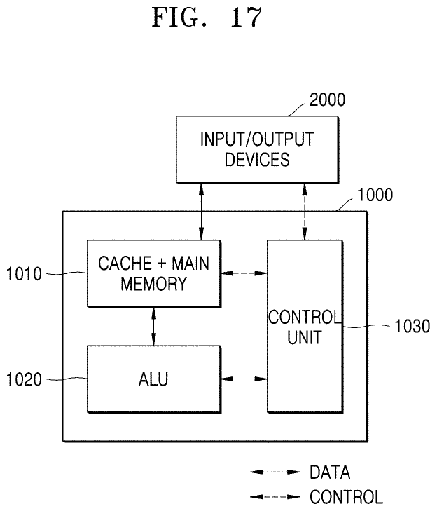

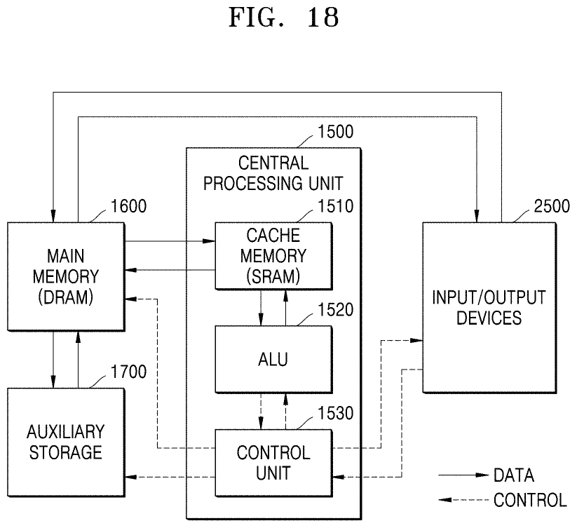

FIGS. 17 and 18 are conceptual diagrams schematically illustrating a device architecture that can be applied to an electronic device according to an example embodiment.

Referring to FIG. 17, an electronic device architecture 1000 may include a memory unit 1010 and a control unit 1030, and may further include an arithmetic logic unit (ALU) 1020. The memory unit 1010, the ALU 1020, and the control unit 1030 may be electrically connected to one another. For example, the electronic device architecture 1000 may be implemented as one chip including the memory unit 1010, the ALU 1020, and the control unit 1030. Specifically, the memory unit 1010, the ALU module 1020, and the control unit 1030 may be connected to each other by a metal line in an on-chip and directly communicate with each other. The memory unit 1010, the ALU module 1020, and the control unit 1030 may be integrated monolithically on one substrate to constitute one chip. An input/output device 2000 may be connected to the electronic device architecture (chip) 1000. In addition, the memory unit 1010 may include both a main memory and a cache memory. The electronic device architecture (chip) 1000 may be an on-chip memory processing unit. The memory unit 1010, the ALU module 1020, and/or the control unit 1030 may each independently include a semiconductor device according to the embodiments described above.

Referring to FIG. 18, a cache memory 1510, an ALU unit 1520, and a control unit 1530 may constitute a central processing unit (CPU) 1500, and the cache memory 1510 may be a static random access memory (SRAM). Apart from the CPU 1500, a main memory 1600 and an auxiliary storage 1700 may be provided, or input/output devices 2500 may be provided. The main memory 1600 may be, for example, a dynamic random access memory (DRAM) and may include a semiconductor device according to the above-described embodiments.

In some cases, an electronic device architecture may be implemented in a form in which computing unit devices and memory unit devices are adjacent to each other in one chip, regardless of distinction of sub-units.

According to the example embodiments, the doping concentration of the semiconductor substrate may be adjusted to be lower than the majority carrier concentration of the channel layer, and the thickness of the channel layer may be adjusted to be thin to form a channel having a p-n junction between the semiconductor substrate and the channel layer. In this case, the semiconductor substrate may change the polarization direction of the ferroelectric layer even at a low voltage by supplying, to the channel layer, minority carriers capable of helping a depletion operation and an inversion operation. Accordingly, a large memory window (MW) and an excellent retention characteristic of the semiconductor device may be secured. In addition, when the channel layer is formed of a two-dimensional semiconductor material, durability of the semiconductor device may be improved.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although the semiconductor device and the electronic device including the semiconductor device described above have been described with reference to the embodiments illustrated in the drawing, it should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of inventive concepts as defined by the following claims.

What is claimed is:

1. A semiconductor device comprising:
a semiconductor substrate including a dopant having a polarity;
a channel layer on the semiconductor substrate and including majority carriers having a polarity opposite a polarity of the semiconductor substrate;
a ferroelectric layer on the channel layer; and
a gate on the ferroelectric layer, wherein
a doping concentration of the semiconductor substrate is less than a concentration of the majority carriers of the channel layer.

2. The semiconductor device of claim 1, wherein
the doping concentration of the semiconductor substrate is about 10¹⁶ to about 10¹⁹ cm⁻³.

3. The semiconductor device of claim 1, wherein the concentration of the majority carriers of the channel layer is about 10¹⁸ to about 10²¹ cm⁻³.

4. The semiconductor device of claim 1, wherein the channel layer has a thickness of about 5 nm or less.

5. The semiconductor device of claim 1, wherein the semiconductor substrate includes a group IV semiconductor material.

6. The semiconductor device of claim 1, wherein the channel layer includes an oxide semiconductor or a two-dimensional (2D) semiconductor material.

7. The semiconductor device of claim 1, wherein the dopant in the semiconductor substrate is a p-type dopant.

8. The semiconductor device of claim 1, wherein the channel layer includes an oxide of at least one of In, Ga, Zn, and Sn.

9. The semiconductor device of claim 1, wherein the channel layer includes graphene or transition metal dichalcogenide (TMD).

10. The semiconductor device of claim 1, wherein the dopant in the semiconductor substrate is an n-type dopant.

11. The semiconductor device of claim 1, wherein the channel layer includes an oxide of at least one of Sn and Ni.

12. The semiconductor device of claim 1, wherein the channel layer includes black phosphorous.

13. The semiconductor device of claim 1, wherein the ferroelectric layer includes at least one of hafnium oxide, zirconium oxide, and hafnium-zirconium oxide.

14. The semiconductor device of claim 1, wherein the channel layer, the ferroelectric layer, and the gate sequentially surround the semiconductor substrate.

15. A semiconductor device comprising:
a substrate; and
a first field effect transistor and a second field effect transistor on the substrate,
wherein the first field effect transistor includes
a first semiconductor layer including a first dopant having a polarity,
a first channel layer on the first semiconductor layer and including majority carriers having a polarity opposite a polarity of the first semiconductor layer,
a first ferroelectric layer on the first channel layer, and
a first gate on the first ferroelectric layer, and
wherein the second field effect transistor includes
a second semiconductor layer including a second dopant having a polarity opposite the polarity of the first semiconductor layer;
a second channel layer on the second semiconductor layer and including majority carriers having a polarity opposite to a polarity of the second semiconductor layer,
a second ferroelectric layer on the second channel layer, and
a second gate on the second ferroelectric layer,
wherein a doping concentration of the first semiconductor layer is less than a concentration of the majority carriers of the first channel layer, and
wherein a doping concentration of the second semiconductor layer is less than a concentration of the majority carriers of the second channel layer.

16. The semiconductor device of claim 15, wherein the first channel layer and the second channel layer independently each have a thickness of about 5 nm or less.

17. The semiconductor device of claim 15, wherein the first channel layer and the second channel layer each independently include an oxide semiconductor or a two-dimensional semiconductor material.

18. The semiconductor device of claim 15, wherein
the first channel layer is directly on the first semiconductor layer, and
an interface between the first channel layer and the first semiconductor layer includes a pn junction.

19. The semiconductor device of claim 15, wherein
the first field effect transistor further includes a first source connected to a first side of the first channel layer and a first drain connected to a second side of the first channel layer,
the first side of the first channel layer and the second side of the first channel layer are different sides of the first channel layer,
the second field effect transistor further includes a second source connected to a first side of the second channel layer and a second drain connected to a second side of the second channel layer, and
the first side of the second channel layer and the second side of the second channel layer are different sides of the second channel layer.

20. The semiconductor device of claim 19, wherein
the first ferroelectric layer extends between the first source and the first drain, between the first gate and the first source, and between the first gate and the first drain, and
the second ferroelectric layer extends between the second source and the second drain, between the second gate and the second source, and between the second gate and the second drain.
